(19) United States
(12) Patent Application Publication
(10) Pub. No.: US 2018/0041007 A1
(43) Pub. Date: Feb. 8, 2018

(54) TEMPERATURE CONTROL CIRCUIT, TRANSMITTER, AND TEMPERATURE CONTROL METHOD

(71) Applicant: Mitsubishi Electric Corporation, Chiyoda-ku (JP)

(72) Inventor: Tetsuro ASHIDA, Tokyo (JP)

(73) Assignee: Mitsubishi Electric Corporation, Chiyoda-ku (JP)

(21) Appl. No.: 15/537,750

(22) PCT Filed: May 27, 2015
(86) PCT No.: PCT/JP2015/065313

§ 371 Date: Jun. 19, 2017

(51) Int. Cl. H01S 5/06; H01S 5/068; H01S 5/024

(52) U.S. Cl. CPC H01S 5/0612; H01S 5/02415; H01S 5/06808

(57) ABSTRACT

A temperature control circuit includes a temperature detector to detect temperature of an LD, a TEC to control temperature of the LD, a current calculation circuit to calculate an amount of current caused to flow through the TEC on the basis of a temperature of the LD and a target temperature, a current control circuit to control current to flow through the TEC on the basis of the amount of current, and a target temperature calculation circuit to set a first target temperature as the target temperature during LD shutdown cancellation, to set the target temperature to monotonously decrease from the first target temperature to a second target temperature lower than the first target temperature until a certain time elapses since an LD shutdown start, and to set the second target temperature as the target temperature when the certain time elapses since the LD shutdown start.

### FIELD

The present invention relates to a temperature control circuit for controlling the temperature of a laser diode, a transmitter, and a temperature control method.

### BACKGROUND

In recent years, an increase in the transmission capacity of optical communication is demanded. In order to increase the transmission capacity of optical communication, studies have been conducted on a technique, such as wavelength multiplex (Wavelength Division Multiplex: WDM) or time wavelength division multiplex (Time Wavelength Division Multiplex: TWDM) with which optical signals of a plurality of wavelengths are transmitted through one optical fiber. In a transmission scheme using wavelength multiplexing, it is very important to enhance the stability of wavelength of output light in an optical transmitter. On the other hand, in an LD (Laser Diode: laser diode) element used for optical transmitters, the wavelength of output light fluctuates depending on the operation temperature. Accordingly, when transmission is performed using wavelength multiplexing, it is necessary to perform LD temperature constant control with high accuracy that causes to stabilize the LD temperature, i.e., the temperature of an LD to keep the wavelength of output light constant.

However, when the heat generation amount varies due to an instantaneous change in current for driving the LD and the LD temperature constant control cannot respond to the variation, the LD temperature fluctuates and causes the wavelength of output light to deviate from a desired wavelength range. Particularly, an LD shutdown function of turning off the optical output of an LD, i.e., a light emission stopping function is used in optical communications, and when a failure has occurred on a transmission path, an LD shutdown operation is performed on the basis of a command from the system. Thus, in optical communications, the LD current is likely to abruptly fluctuate. Particularly, in TWDM-PON (Passive Optical Network) discussed as a next generation optical access system, an LD shutdown operation is frequently performed to drive a transmitter in bursts, i.e., intermittently.

In order to prevent the LD oscillation wavelength from deviating from a desired range due to temperature fluctuations, Patent Literature 1 proposes a technique of performing control to lower the LD temperature in the LD shutdown time.

### CITATION LIST

### Patent Literature

Patent Literature 1: Japanese Patent Application Laid-open No. 2011-29378

### SUMMARY

### Technical Problem

Meanwhile, according to the above conventional technique, LD temperature control is performed in the LD shutdown time by lowering a target temperature by a constant amount, to reduce the deviation of the LD oscillation wavelength in the LD shutdown time. In this case, if a short term LD shutdown is indicated a plurality of times successively, a sudden change of the target temperature for LD temperature control is made frequently. This can be a factor of causing wavelength fluctuations. Further, because the target temperature is switched in response to high speed switching between the LD shutdown and LD shutdown cancellation, there is a problem in that a circuit for controlling a current that flows into a thermoelectric element for adjusting the laser diode temperature may start oscillation, and a large current keeps flowing through the thermoelectric element.

The present invention has been made in view of the above, and an object of the present invention is to provide a temperature control circuit, a transmitter, and a temperature control method which can reduce the deviation of the LD oscillation wavelength due to an LD shutdown operation.

### Solution to Problem

In order to solve the above problems and achieve the object, a temperature control circuit according to the present invention includes: a temperature detector to detect temperature of a laser diode; a thermoelectric element to control temperature of the laser diode by performing heat absorption and radiation in accordance with an amount of current flowing therethrough; a current calculation unit to calculate an amount of current caused to flow through the thermoelectric element on a basis of a temperature of the laser diode detected by the temperature detector and a target temperature; a current control unit to control a current caused to flow through the thermoelectric element on a basis of an amount of current calculated by the current calculation unit; and a target temperature calculation unit to set a first target temperature as the target temperature, during a time period in which the light emission stop state of the laser diode is cancelled on a basis of a light emission stop signal that indicates whether to cause the laser diode to be in a light emission stop state, to set the target temperature so as to monotonously decrease from the first target temperature to a second target temperature that is lower than the first target temperature until a certain time elapses since the light emission stop state of the laser diode has started in the light emission stop signal, and to set the second target temperature as the target temperature when the certain time elapses since the light emission stop state of the laser diode has started in the light emission stop signal.

### Advantageous Effects of Invention

The temperature control circuit according to the present invention has an effect capable of reducing the deviation of the LD oscillation wavelength due to an LD shutdown operation.

### BRIEF DESCRIPTION OF DRAWINGS

FIG. 1 is a block diagram illustrating a configuration example of an optical transmitter according to a first embodiment.

FIG. 2 illustrates a configuration example of a control circuit according to the first embodiment.

FIG. 3 is a flowchart illustrating an example of a process procedure by a current calculation circuit according to the first embodiment.

FIG. 4 illustrates an example of a table showing the correlation between the temperature change amount and the current amount, according to the first embodiment.

FIG. 5 illustrates examples of a fluctuation in light oscillation wavelength with an LD shutdown signal, in a case where temperature constant control is performed.

FIG. 6 illustrates an example of the relationship between the LD shutdown length and the wavelength fluctuation amount of the LD light oscillation wavelength.

FIG. 7 illustrates an example of a change in LD light emission wavelength, in a case where the LD shutdown length is set to Tₛₚₐₙ when the temperature constant control is performed.

FIG. 8 schematically illustrates an example of the relationship between the LD temperature and the LD light oscillation wavelength.

FIG. 9 illustrates an example of a target temperature calculated by a target temperature calculation circuit during an LD shutdown, according to the first embodiment.

FIG. 10 is a flowchart illustrating an example of a target temperature calculation procedure by a target temperature calculation circuit according to the first embodiment.

FIG. 11 illustrates an example of a fluctuation in LD light oscillation wavelength, in a case where the LD shutdown duration time is long, according to the first embodiment.

FIG. 12 illustrates an example of fluctuations in LD light oscillation wavelength, in a case where an LD shutdown having short duration is performed highly frequently, according to the first embodiment.

FIG. 13 is a flowchart illustrating an example of a target temperature calculation procedure by a target temperature calculation circuit according to a second embodiment.

FIG. 14 illustrates an example of a target temperature calculated by a target temperature calculation process and to be set in a current calculation circuit, according to the second embodiment.

FIG. 15 illustrates a configuration example of an optical communication system according to a third embodiment.

### DESCRIPTION OF EMBODIMENTS

Exemplary embodiments of a temperature control circuit, a transmitter, and a temperature control method according to the present invention will be explained below in detail with reference to the accompanying drawings. The present invention is not limited to the following embodiments.

### First Embodiment

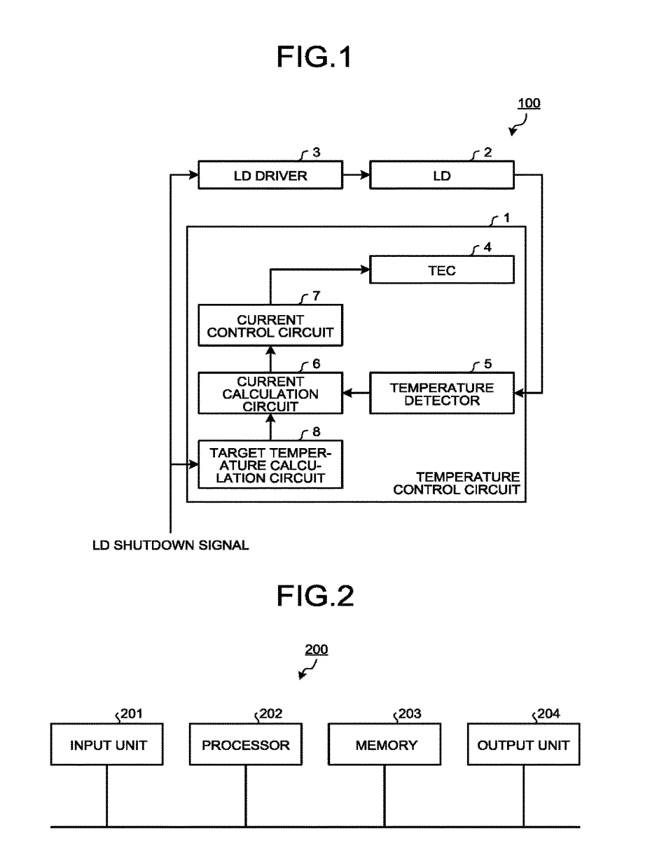

FIG. 1 is a block diagram illustrating a configuration example of an optical transmitter according to a first embodiment of the present invention. The optical transmitter 100 according to this embodiment includes an LD (Laser Diode: laser diode) 2 that serves as a light emission element and outputs an optical signal, an LD driver 3 for driving the LD 2, and a temperature control circuit 1 that controls the temperature of the LD 2. The temperature control circuit 1 includes a TEC (ThermoElectric Coolers) 4, a temperature detector 5, a current calculation circuit 6, a current control circuit 7, and a target temperature calculation circuit 8. The TEC 4 is a thermoelectric element that performs heat absorption and radiation in accordance with current control and changes the temperature of the LD 2. The temperature detector 5 is a temperature sensor that detects the temperature of the LD 2. As a temperature detector 5, for example, a thermoelectric couple, thermometric resistor, thermistor, IC (Integrated Circuit) temperature sensor, or the like may be used. The current calculation circuit 6 is a current calculation unit that calculates the amount and direction of current caused to flow through the TEC 4 on the basis of a temperature detected by the temperature detector 5 and a target temperature. The current control circuit 7 serving as a current control unit is an electronic circuit that causes a current to flow through the TEC 4, on the basis of the amount and direction of current calculated by the current calculation unit 6. The target temperature calculation circuit 8 is a target temperature calculation unit that calculates a target temperature to be set in the current calculation circuit 6, on the basis of an LD shutdown signal serving as a light emission stop signal. The LD shutdown signal is a signal input from outside the optical transmitter 100, and serves as a signal for instructing whether to set the optical output of the LD 2 into a shutdown state, i.e., a light emission stop state. Here, an explanation will be given by taking the TEC 4 as an example; however, any element can be used instead as long as it is an element that performs thermoelectric conversion.

Among the circuits that constitute the temperature control circuit 1, each of the current calculation circuit 6 and the target temperature calculation circuit 8 may be composed of an electronic circuit, or a control circuit such as an MCU (Micro Controller Unit) or multifunctional IC may be implemented as one or more of the current calculation circuit 6 and the target temperature calculation circuit 8.

When each of the current calculation circuit 6 and the target temperature calculation circuit 8 is implemented as a control circuit, as described above, this control circuit has the configuration illustrated in FIG. 2, for example. FIG. 2 illustrates a configuration example of a control circuit 200. The control circuit 200 includes an input unit 201 serving as a reception unit that receives data input from outside, a processor 202, a memory 203, and an output unit 204 serving as a transmission unit that transmits data to outside. The input unit 201 is an interface circuit that receives data input from outside the control circuit 200, and gives the input data to the processor 202. The output unit 204 is an interface circuit that sends data, which is from the processor 202 or memory 203, to outside the control circuit 200. When one or more of the current calculation circuit 6 and the target temperature calculation circuit 8 are realized by the control circuit 200, each circuit realized by the control circuit 200 is achieved by the processor 202 in reading a program corresponding thereto stored in the memory 203 and executing the program. Further, the memory 203 is used also as a temporary memory in each process performed by the processor 202.

Next, an explanation will be given of an operation of the temperature control circuit 1 according to this embodiment. First, the temperature detector 5 detects the temperature of the LD 2. By the use of the temperature of the LD 2 detected by the temperature detector 5, the current calculation circuit 6 calculates the amount and direction of current caused to flow through the TEC 4 so that the temperature of the LD 2 approaches a target temperature set by the target temperature calculation circuit 8. For example, the current calculation circuit 6 holds therein the correlation between the temperature change amount and the current amount, and obtains, based thereon, the amount and direction of current necessary for cancelling the temperature difference between the target temperature and the temperature of the LD 2.

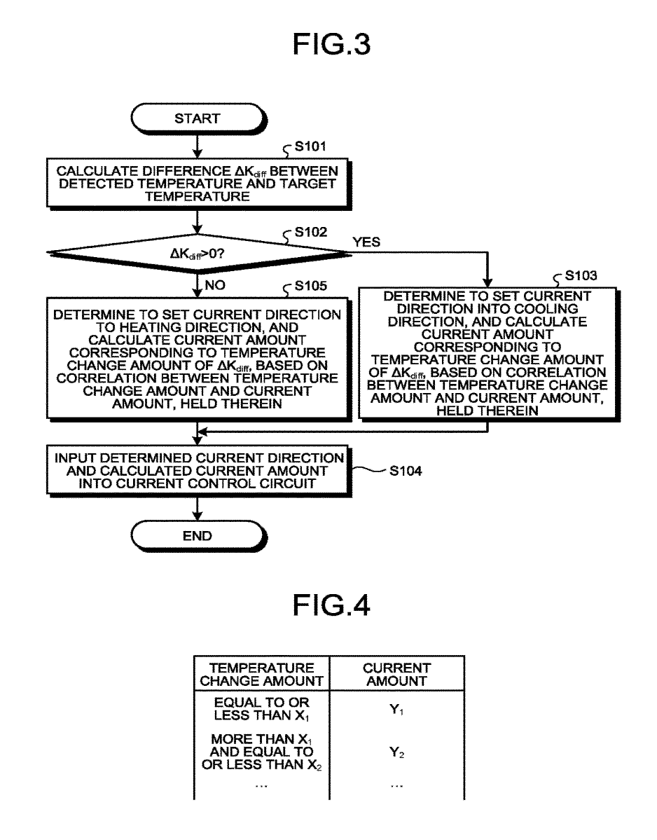

FIG. 3 is a flowchart illustrating an example of a process procedure by the current calculation circuit 6 according to this embodiment. As illustrated in FIG. 3, the current calculation circuit 6 calculates the difference ΔK_{diff} between a detected temperature, i.e., the temperature of the LD 2 detected by the temperature detector 5, and a target temperature (step S101). Then, the current calculation circuit 6 determines whether ΔK_{diff} is larger than zero (step S102). When ΔK_{diff} is larger than zero (Yes at step S102), the current calculation circuit 6 determines to set the current direction to a cooling direction, i.e., a current direction for the TEC 4 to perform cooling. Further, on the basis of the correlation between the temperature change amount and the current amount, which is held therein, the current calculation circuit 6 calculates a current amount corresponding to a temperature change amount of ΔK_{diff}, i.e., a current amount corresponding to a case where the temperature change amount is ΔK_{diff} (step S103). Here, the current calculation circuit 6 holds the correlation between the temperature change amount and the current amount, for example, as a table, in an internal or external memory. FIG. 4 illustrates an example of a table showing the correlation between the temperature change amount and the current amount. However, the correlation between the temperature change amount and the current amount may be held by the use of a calculation formula in place of a table. Specifically, the correlation between the temperature change amount and the current amount may be held such that the current amount is predetermined as a function of the temperature change amount and this function is set in the current calculation circuit 6. Further, with respect to the TEC 4, the current direction to be applied for cooling and the current direction to be applied for heating are opposite to each other. Accordingly, the current calculation circuit 6 decides the current direction to be applied to the TEC 4, in accordance with whether cooling is required or heating is required.

The current calculation circuit 6 inputs the decided current direction and the calculated current amount into the current control circuit 7 (step S104), and then ends the process. On the other hand, at step S102, when ΔK_{diff} is equal to or less than zero (No at step S102), the current calculation circuit 6 determines to set the current direction to a heating direction, i.e., a current direction for the TEC 4 to perform heating. Further, on the basis of the correlation between the temperature change amount and the current amount, which is held therein, the current calculation circuit 6 calculates a current amount corresponding to a temperature change amount of ΔK_{diff}, i.e., a current amount corresponding to a case where the temperature change amount is ΔK_{diff} (step S105), and then the procedure proceeds to step S104. Here, the method of holding the correlation between the temperature change amount and the current amount is the same as that of step S102. The same table or calculation formula may be used for both of the heating and the cooling, or individual tables or calculation formulas may be used for the heating and the cooling.

The current control circuit 7 causes a current to flow through TEC 4, on the basis of the amount and direction of current calculated by the current calculation circuit 6. The target temperature calculation circuit 8 sets a target temperature in the current calculation circuit 6 on the basis of an LD shutdown signal. On the basis of the LD shutdown signal, the target temperature calculation circuit 8 sets a target temperature for the LD shutdown cancellation time in the current calculation circuit 6 while the LD shutdown is cancelled. While the LD shutdown is indicated, the target temperature calculation circuit 8 calculates a target temperature for the LD shutdown time described later, and sets the calculated target temperature in the current calculation circuit 6. The target temperature for the LD shutdown cancellation time may be set to any temperature, as long as the corresponding light oscillation wavelength of the LD 2 falls within a desired wavelength range.

Next, an explanation will be given of a method of calculating the target temperature for the LD shutdown time, according to this embodiment. First, an explanation will be given of the relationship between the LD shutdown signal and the wavelength of an optical signal output from the LD 2, i.e., the light oscillation wavelength. Here, an example is assumed where the temperature of the LD 2 is controlled to a fixed target temperature. In this case, during the LD shutdown time period i.e., a light emission stop time period of the LD 2, the drive current of the LD 2 decreases, and the heat generation amount of the LD 2 is reduced, and so the temperature of the LD 2 falls. Accordingly, in the LD shutdown cancellation time, the current caused to flow through the TEC 4 is increased to recover the temperature lowered as described above, back to the target temperature. Thus, the temperature of the LD 2 temporary rises, and the light oscillation wavelength of the LD 2 is changed due to the temperature rise of the LD 2.

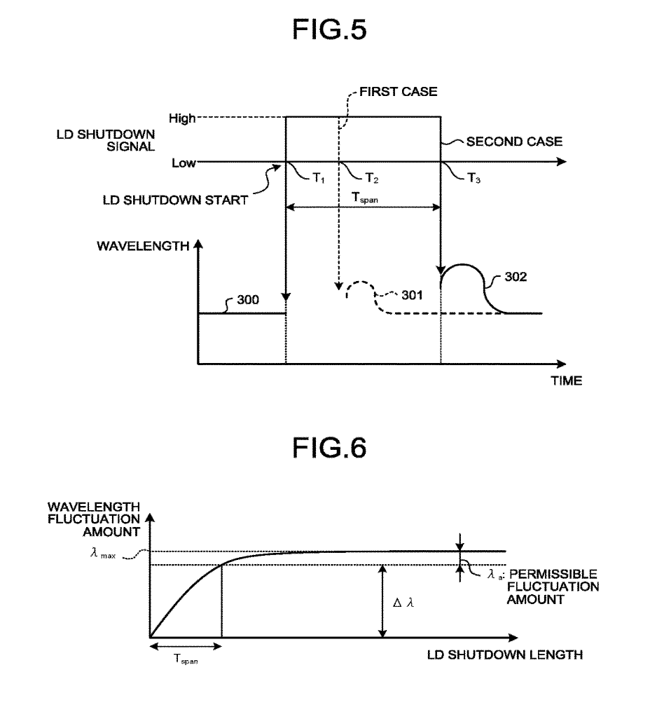

FIG. 5 illustrates examples of a fluctuation in light oscillation wavelength with an LD shutdown signal, in a case where temperature constant control is performed. FIG. 5 illustrates fluctuated states of the light oscillation wavelength and the LD shutdown signal, in a case where temperature constant control, i.e., control of setting the target temperature to be the same at the LD shutdown time and at the LD shutdown time, is performed. The upper side of FIG. 5 illustrates the LD shutdown signal, and the lower side of FIG. 5 illustrates the wavelength of an optical signal output from the LD 2, i.e., the light oscillation wavelength of the LD 2. The LD shutdown signal is a signal input from outside the optical transmitter 100, and, as illustrated in FIG. 5, while the LD shutdown is indicated to perform, i.e., while a light emission stop of the LD 2 is indicated, the LD shutdown signal takes a value of High. Further, while the LD shutdown cancellation is indicated, i.e., while light emission of the LD 2 is permitted, the LD shutdown signal takes a value of Low.

Here, FIG. 5 illustrates a mere example of the correlation between the signal value and whether the LD shutdown is indicated or cancelled. Specific signal values indicating whether the LD shutdown is indicated or cancelled, i.e., whether the LD shutdown is significant, are not limited to the example of FIG. 5. For example, it may be configured such that the LD shutdown is indicated when the LD shutdown signal is Low, and the LD shutdown is cancelled when the signal is High. In the following description, as in the example illustrated in FIG. 5, an explanation will be given on the premise that the LD shutdown is indicated when the LD shutdown signal is High, and the LD shutdown is cancelled when the signal is Low.

As illustrated in FIG. 5, when the LD shutdown signal changes from Low to High, the LD driver 3 stops the light emission of the LD 2. Hereinafter, a change of the LD shutdown signal from Low to High will be referred to as “LD shutdown start”, as needed. Further, a change of the LD shutdown signal from High to Low will be referred to as “LD shutdown end”, as needed. FIG. 5 illustrates fluctuations in the wavelength of light output from the LD 2 in two cases for each of which the time from the LD shutdown start to the LD shutdown end is different. In FIG. 5, when the above two cases are assumed as a first case and a second case, T₁ denotes the point in time of the LD shutdown start in both of the first case and the second case. T₂ denotes the point in time of the LD shutdown end in the first case. T₃ denotes the point in time of the LD shutdown end in the second case. The time length from T1 to T2 is shorter than the time length from T1 to T3. In other words, the second case is longer in LD shutdown duration time than the first case.

A light oscillation wavelength 300 on the lower side of FIG. 5 illustrates the light oscillation wavelength of the LD 2 before the LD shutdown start. In the example of FIG. 5, it is assumed that, before the LD shutdown start, the light oscillation wavelength of the LD 2 is stably controlled, and the light oscillation wavelength of the LD 2 before the LD shutdown start is the same in the first case and the second case. A light oscillation wavelength 301 on the lower side of FIG. 5 corresponds to the first case, and illustrates the light oscillation wavelength of the LD 2 after the LD shutdown end. A light oscillation wavelength 302 on the lower side of FIG. 5 corresponds to the second case, and illustrates the light oscillation wavelength of the LD 2 after the LD shutdown end. As illustrated in FIG. 5, it can be understood that, in the second case in which the LD shutdown duration time is longer than that of the first case, the wavelength fluctuation amount from the time of the LD shutdown start is larger than that of the first case. This is because, as the LD shutdown time period is longer, a decrease amount in the temperature of the LD 2 becomes larger, and the current caused to flow through the TEC 4 after the LD shutdown end is increased.

FIG. 6 illustrates an example of the relationship between the LD shutdown length and the wavelength fluctuation amount of the light oscillation wavelength of the LD 2. As in the example of FIG. 5, FIG. 6 illustrates the LD shutdown length, i.e., LD shutdown duration time and the wavelength fluctuation amount of the light oscillation wavelength of the LD 2, in a case where temperature constant control is performed. Further, as illustrated in FIG. 5, the light oscillation wavelength of the LD 2 changes to increase from the LD shutdown end time and then decreases. As the LD light wavelength fluctuation amount, FIG. 6 illustrates the maximum fluctuation amount, i.e., an amount corresponding to the top of a ridge illustrated by each of the light oscillation wavelengths 301 and 302 of FIG. 5. In FIG. 6, the horizontal axis denotes the LD shutdown length, and the vertical axis denotes the wavelength fluctuation amount of the light oscillation wavelength of the LD 2, i.e., a deviation amount from the light oscillation wavelength of the LD 2 before the LD shutdown start. As illustrated in FIG. 6, as the LD shutdown length is longer, the wavelength fluctuation amount of the light oscillation wavelength of the LD 2 increases. However, as the LD shutdown length exceeds a certain extent, the wavelength fluctuation amount lowers its increasing rate and converges to a constant value. This constant value is referred to as the maximum value λₘₐₓ of the wavelength fluctuation amount. Specifically, λₘₐₓ is a value at which a change amount in the wavelength fluctuation amount of the light oscillation wavelength with respect to the LD shutdown length becomes less than a threshold. Here, this threshold is a value for determining the convergence, and can be a value smaller than a design value with which the designer determines the arrival of convergence. For example, it is assumed that the change amount in the wavelength fluctuation amount is defined by a ratio of the absolute value of a change amount in the wavelength fluctuation amount per unit time, relative to a wavelength fluctuation amount before the change, i.e., it is assumed that the change amount in the wavelength fluctuation amount is defined by |r_{ref}′−r_{ref}|/r_{ref}, where r_{ref} is a wavelength fluctuation amount at a time t_{ref}, and r_{ref}′ is a wavelength fluctuation amount after a unit time tᵤₙᵢₜ from the time t_{ref}. In this case, the above threshold is set to 0.001. However, the method of defining the threshold and a specific value of the threshold are not limited to this example. On the other hand, there is a case where a wavelength fluctuation amount permissible in the optical transmitter 100 has been defined. In this case, a wavelength fluctuation amount permissible therein, i.e., a permissible fluctuation amount, is set as λₐ.

The LD driver 3 supplies an LD drive current while causing the LD 2 to emit light; however, when an LD shutdown is indicated, the LD driver 3 reduces the LD drive current to stop the light emission of the LD 2. Consequently, after the LD shutdown start, the temperature of the LD 2 falls. On the other hand, the LD drive current during the LD shutdown does not change and remains low, and, as the time elapses from the LD shutdown start, the temperature of the LD 2 approaches a steady state and the temperature change becomes moderate. Accordingly, as illustrated in FIG. 6, as the LD shutdown length exceeds a certain extent, the change amount in the wavelength fluctuation amount of the LD 2 with respect to the LD shutdown length decreases, and the wavelength fluctuation amount approaches a constant value.

In this embodiment, the relationship between the LD shutdown length and the wavelength fluctuation amount of the light oscillation wavelength of the LD 2, in a case where the temperature constant control illustrated in FIG. 6 is performed, is obtained in advance on the basis of measurement or on the basis of calculation measurement using a design value. Then, the relationship illustrated in FIG. 6 is used to calculate Tₛₚₐₙ, which is the minimum value of the LD shutdown length for causing the wavelength fluctuation amount to be equal to or more than Δλ=λₘₐₓ−λₐ. Here, λₐ may be zero. In this case, Tₛₚₐₙ is the minimum value of the LD shutdown length with which the wavelength fluctuation amount becomes λₘₐₓ.

Specifically, it is assumed that a first wavelength fluctuation amount denotes the minimum value of the LD shutdown length with which the change amount in the wavelength fluctuation amount of the light oscillation wavelength of the LD 2 with respect to the LD shutdown length becomes less than the threshold. In this case, Tₛₚₐₙ consisting of a certain time is an LD shutdown length corresponding to a second wavelength fluctuation amount that is a value obtained by subtracting the permissible fluctuation amount from the first wavelength fluctuation amount. Here, the first wavelength fluctuation amount is calculated by the use of the relationship between the LD shutdown length, which is the LD shutdown duration time, and the wavelength fluctuation amount of the light oscillation wavelength of the LD 2.

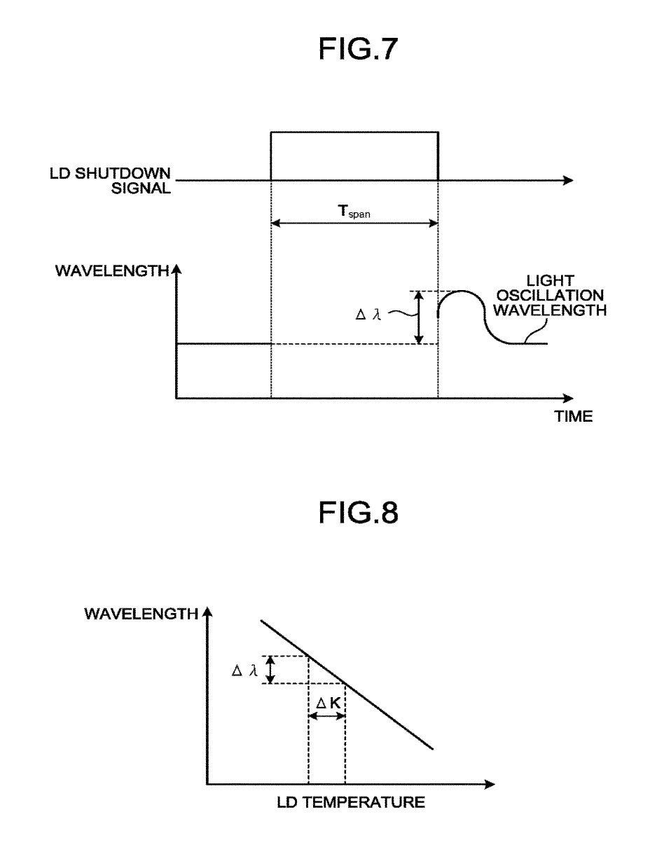

FIG. 7 illustrates an example of a change in the light emission wavelength of the LD 2, in a case where the LD shutdown length is set to Tₛₚₐₙ when the temperature constant control is performed. The upper side of FIG. 7 illustrates the LD shutdown signal, and the lower side of FIG. 7 illustrates the light oscillation wavelength of the LD 2. When the LD shutdown length is set to Tₛₚₐₙ and the temperature constant control is performed, the wavelength fluctuation amount at the LD shutdown end time becomes Δλ, as illustrated in FIG. 7.

In this embodiment, by the use of the above described relationship between the LD shutdown length and the wavelength fluctuation amount of the light oscillation wavelength of the LD 2, and the relationship between the temperature of the LD 2 and the wavelength fluctuation amount of the light oscillation wavelength of the LD 2, the target temperature to be set in the current calculation circuit 6 is linearly lowered until the elapsed time since the LD shutdown start becomes Tₛₚₐₙ. Next, an explanation will be given of a method of calculating the target temperature after the LD shutdown start that is performed by the target temperature calculation circuit 8 according to this embodiment.

FIG. 8 schematically illustrates an example of the relationship between the temperature of the LD 2 and the light oscillation wavelength of the LD 2. Here, in FIG. 8, the relationship between the temperature of the LD 2 and the light oscillation wavelength of the LD 2 is illustrated as being linear; however, the relationship between the temperature of the LD 2 and the light oscillation wavelength of the LD 2 may not be necessarily linear. In this embodiment, the target temperature calculation circuit 8 holds the relationship between the temperature of the LD 2 and the light oscillation wavelength of the LD 2 as temperature versus wavelength characteristics in the form of a table, an approximate expression, or the like. Alternatively, in this embodiment, it is sufficient that a temperature change amount corresponding to Δλ is obtained as described later; accordingly, when Δλ is fixed, the target temperature calculation circuit 8 may hold only the temperature change amount corresponding to Δλ.

On the basis of Δλ and the temperature versus wavelength characteristics, the target temperature calculation circuit 8 calculates ΔK, which is a temperature change amount for lowering the target temperature during the LD shutdown. Here, ΔK is the absolute value of the temperature change amount. Specifically, the target temperature calculation circuit 8 calculates a temperature change amount corresponding to Δλ by the use of temperature versus wavelength characteristics, and sets the temperature change amount as ΔK. Δλ is expressed by λₘₐₓ−λₐ, as described above. By the use of ΔK thus calculated, the target temperature calculation circuit 8 lowers the temperature with an inclination of ΔK/Tₛₚₐₙ from the LD shutdown start, until the elapsed time since the LD shutdown start becomes Tₛₚₐₙ, and then sets the target temperature to a constant value in a time period in which the elapsed time since the LD shutdown start is Tₛₚₐₙ or more. As described with reference to FIG. 6, when the LD shutdown duration time is Tₛₚₐₙ or more, the temperature change of the LD 2 is small, and even when the light oscillation wavelength fluctuates, the fluctuation amount is λₐ, which is equal to or smaller than the permissible wavelength fluctuation amount. Accordingly, when the elapsed time is Tₛₚₐₙ or more, the target temperature is set to a constant value.

Specifically, until the elapsed time since the LD shutdown start becomes Tₛₚₐₙ, the target temperature calculation circuit 8 linearly lowers the target temperature with an inclination of a value, which is calculated by dividing by Tₛₚₐₙ a value obtained by subtracting a second target temperature from a first target temperature.

Here, the explanation has been given to calculate ΔK from Δλ; however, when the temperature versus wavelength characteristics are approximated, ΔK is used as a fixed value after ΔK is once calculated on the basis of Δλ.

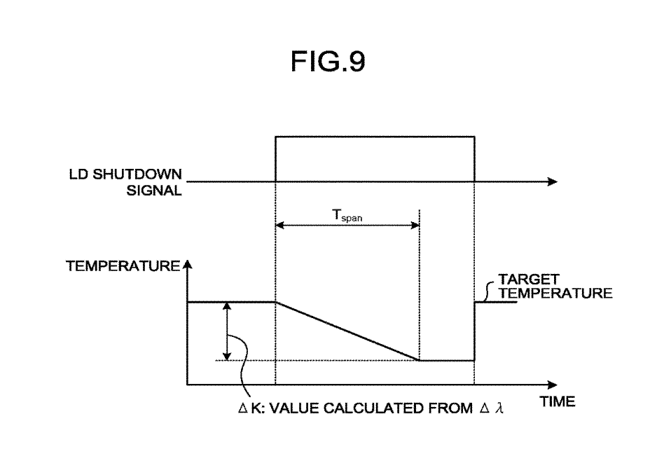

FIG. 9 illustrates an example of the target temperature calculated by the target temperature calculation circuit 8 during the LD shutdown. The upper side of FIG. 9 illustrates the LD shutdown signal, and the lower side of FIG. 9 illustrates the target temperature calculated by the target temperature calculation circuit 8. As illustrated in FIG. 9, the target temperature calculation circuit 8 lowers the target temperature with an inclination of ΔK/Tₛₚₐₙ from the LD shutdown start, until the elapsed time since the LD shutdown start becomes Tₛₚₐₙ. When a first target temperature denotes a target temperature set at the time of the LD shutdown start, i.e., the target temperature set for the LD shutdown cancellation time, and “t” denotes the elapsed time since the LD shutdown start, the target temperature until the elapsed time since the LD shutdown start becomes Tₛₚₐₙ is expressed by “first target temperature−(ΔK/Tₛₚₐₙ)×t”. When the elapsed time since the LD shutdown start becomes Tₛₚₐₙ or more, the target temperature is set to a second target temperature, which is a constant value of “the first target temperature−ΔK”.

In the example of FIG. 9, a case is illustrated where the LD shutdown duration time is larger than Tₛₚₐₙ. However, as described above, when the LD shutdown duration time is smaller than Tₛₚₐₙ, the target temperature is changed to the target temperature for the LD shutdown cancellation time, at the point in time when the LD shutdown is cancelled.

Further, the first target temperature and the second target temperature described above are preferably determined such that both of the light oscillation wavelength of the LD 2 corresponding to the first target temperature and the light oscillation wavelength thereof corresponding to the second target temperature fall within a desired wavelength range in the optical transmitter 100. Specifically, first, an approximate value of ΔK can be obtained from the characteristics illustrated in FIG. 6. Then, a fluctuation amount of the light oscillation wavelength of the LD 2 corresponding to ΔK can be obtained from the characteristics illustrated in FIG. 8.

Accordingly, for example, a temperature corresponding to a wavelength larger than the lower limit of the desired wavelength range is assumed as the second target temperature. Then, a value obtained by adding ΔK to the second target temperature is assumed as the first target temperature. It suffices that a wavelength corresponding to the first target temperature thus determined falls within the desired wavelength range. When the wavelength corresponding to the first target temperature exceeds the desired wavelength range, the second target temperature is lowered by an extent to be higher than a temperature corresponding to a wavelength larger than the lower limit of the desired wavelength range. In this way, the first target temperature and the second target temperature are determined such that both of the light oscillation wavelength of the LD 2 corresponding to the first target temperature and the light oscillation wavelength thereof corresponding to the second target temperature fall within the desired wavelength range in the optical transmitter 100.

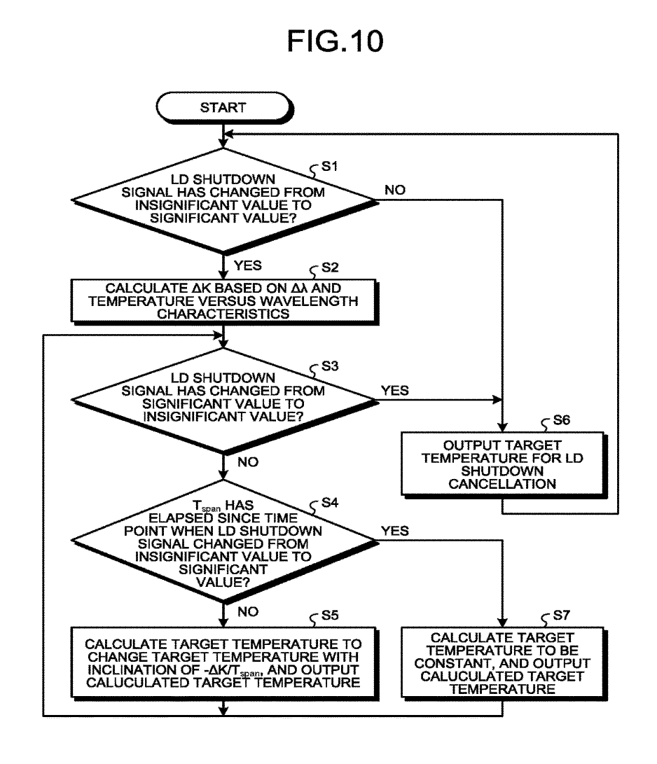

FIG. 10 is a flowchart illustrating an example of a target temperature calculation procedure by the target temperature calculation circuit 8 according to this embodiment. Here, it is assumed that, at the time portion of starting the flowchart of FIG. 10, the LD shutdown signal takes a value indicating Low, i.e., the LD shutdown cancellation, and a target temperature for the LD shutdown cancellation has been set in the current calculation circuit 6. First, the target temperature calculation circuit 8 determines whether the LD shutdown signal has changed from an insignificant value, i.e., Low, to a significant value, i.e., High, (step S1). When the LD shutdown signal has changed from the insignificant value to the significant value (Yes at step S1), the target temperature calculation circuit 8 calculates ΔK on the basis of Δλ and the temperature versus wavelength characteristics (step S2). The target temperature calculation circuit 8 determines whether the LD shutdown signal has changed from the significant value to the insignificant value (step S3). When the LD shutdown signal has not changed from the significant value to the insignificant value (No at step S3), the target temperature calculation circuit 8 determines whether Tₛₚₐₙ has elapsed since the point in time when the LD shutdown signal changed from the insignificant value to the significant value (step S4).

When Tₛₚₐₙ has not elapsed since the point in time when the LD shutdown signal changed from the insignificant value to the significant value (No at step S4), the target temperature calculation circuit 8 calculates a target temperature to change the target temperature with an inclination of −ΔK/Tₛₚₐₙ, i.e., to lower the target temperature with an inclination of ΔK/Tₛₚₐₙ, and outputs the calculated target temperature to the current calculation circuit 6 (step S5). Consequently, the target temperature is set in the current calculation circuit 6. Thereafter, the procedure of the target temperature calculation circuit 8 goes back to step S3.

At step S1, when the LD shutdown signal has not changed from the insignificant value to the significant value (No at step S1), the target temperature calculation circuit 8 outputs the target temperature for the LD shutdown cancellation to the current calculation circuit 6 (step S6), and the procedure goes back to step S1. At step S3, when judging that the LD shutdown signal has changed from the significant value to the insignificant value (Yes at step S3), the procedure proceeds to step S6. At step S4, when judging that Tₛₚₐₙ has elapsed since the point in time when the LD shutdown signal changed from the insignificant value to the significant value (Yes at step S4), the target temperature calculation circuit 8 calculates a target temperature so that the target temperature becomes constant, and outputs the calculated target temperature to the current calculation circuit 6 (step S7), and then the procedure goes back to step S3. At step S7, specifically, the target temperature calculation circuit 8 sets the target temperature to be “first target temperature−ΔK”, as described above.

Next, an explanation will be given of an effect of this embodiment. A case is assumed where temperature constant control is performed by the use of the same target temperature for the LD shutdown time and for the LD shutdown cancellation time, without applying the setting of a target temperature for the LD shutdown time according to this embodiment. In this case, when the LD shutdown is cancelled, an LD drive current flows abruptly through the LD and causes the LD temperature to rise abruptly, and the LD wavelength may shift greatly and deviate from a desired wavelength range.

Further, a case is assumed where a temperature lowered by a constant amount temperature from the target temperature for the LD shutdown cancellation time is used as the target temperature for the LD shutdown time. In this case, when the LD shutdown duration time is long and the LD shutdown is indicated less frequently, the fluctuation amount of the LD light oscillation wavelength can be reduced. On the other hand, when an LD shutdown having short duration is performed highly frequently, a sudden change of the target temperature for LD temperature control is performed frequently, and the operation may become unstable such that the current flowing through the TEC and the LD light oscillation wavelength fluctuate frequently.

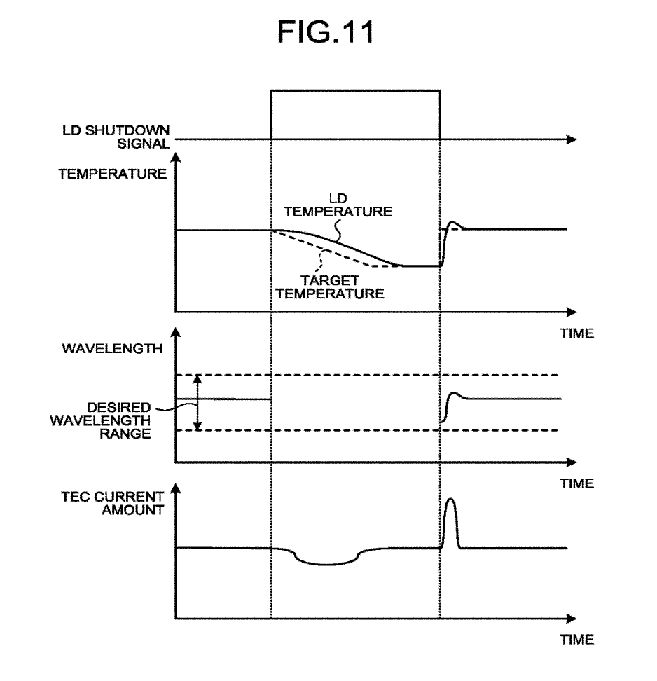

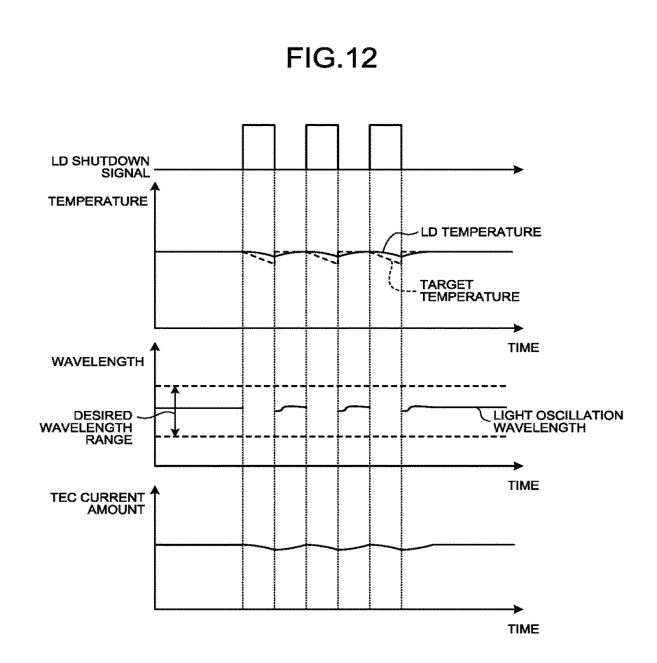

On the other hand, in this embodiment, when the LD shutdown duration time is long, the light oscillation wavelength of the LD 2 can be caused to fall within the desired wavelength range, as illustrated in FIG. 11. Further, even when an LD shutdown having short duration is performed highly frequently, it is possible to cause the light oscillation wavelength of the LD 2 to fall within the desired wavelength range, as illustrated in FIG. 12.

FIG. 11 illustrates an example of a fluctuation in the light oscillation wavelength of the LD 2, in a case where the LD shutdown duration time is long, according to this embodiment. In FIG. 11, the first stage illustrates the LD shutdown signal. The second stage illustrates the LD temperature, i.e., the temperature of the LD 2, and the target temperature to be set in the current calculation circuit 6. The third stage illustrates the light oscillation wavelength of the LD 2. The fourth stage illustrates the TEC current amount, i.e., the amount of current caused to flow through the TEC 4. As illustrated in FIG. 11, because the target temperature to be set in the current calculation circuit 6 is gradually lowered from the LD shutdown start in this embodiment, there is no abrupt change between the currents caused to flow through the TEC 4 before and after the LD shutdown start. In the example of FIG. 11, it is assumed that both of the first target temperature and the second target temperature, i.e., “first target temperature−ΔK”, are determined to fall within the desired wavelength range in the optical transmitter 100. Further, at the LD shutdown end time, the LD 2 is in a state where the temperature thereof is lower than the temperature at the LD shutdown start; accordingly, even when the target temperature is changed at the LD shutdown end time and the temperature of the LD 2 rises, it is possible to cause the light oscillation wavelength of the LD 2 to fall within the desired wavelength range.

FIG. 12 illustrates an example of fluctuations in the light oscillation wavelength of the LD 2, in a case where an LD shutdown having short duration is performed highly frequently, according to this embodiment. In FIG. 12, the first stage illustrates the LD shutdown signal. The second stage illustrates the LD temperature, i.e., the temperature of the LD 2, and the target temperature to be set in the current calculation circuit 6. The third stage illustrates the light oscillation wavelength of the LD 2. The fourth stage illustrates the TEC current amount, i.e., the amount of current caused to flow through the TEC 4. As illustrated in FIG. 12, in this embodiment, the target temperature to be set in the current calculation circuit 6 is gradually lowered from the LD shutdown start, and then, as soon as the LD shutdown is cancelled, the target temperature is returned back to the original, i.e., the target temperature is set to the target temperature before the LD shutdown start. Consequently, even when an LD shutdown having short duration is performed, the target temperature less changes, the current amount of the TEC 4 less fluctuates, and the light oscillation wavelength of the LD 2 also less fluctuates. Accordingly, in this embodiment, it is possible to cause the light oscillation wavelength to fall within the desired wavelength range in a stable state, without allowing a large current to keep flowing through the TEC 4.

As described above, in this embodiment, control is performed such that the target temperature to be set in the current calculation circuit 6 is linearly lowered until the elapsed time since the LD shutdown start becomes Tₛₚₐₙ, and the target temperature is set to be constant when the elapsed time since the LD shutdown start becomes Tₛₚₐₙ or more. Consequently, even when an LD shutdown having short duration is performed highly frequently, the fluctuation in the light oscillation wavelength of the LD 2 can be reduced.

### Second Embodiment

In the first embodiment, the target temperature to be set in the current calculation circuit 6 is linearly lowered until the elapsed time since the LD shutdown start becomes Tₛₚₐₙ. However, in practice, as illustrated in FIG. 6, the relationship between the shutdown signal and the light oscillation wavelength is nonlinear. In consideration of this, in the second embodiment, a nonlinear approximate expression is used to approximate the relationship between the shutdown signal and the light oscillation wavelength on the basis of measurement or design illustrated in FIG. 6. The configuration of an optical transmitter 100 according to this embodiment is the same as that of the optical transmitter 100 according to the first embodiment. Hereinafter, this embodiment will be described with respect to differences from the first embodiment.

As illustrated in FIG. 6, while the LD shutdown length changes from zero to Tₛₚₐₙ, the light oscillation wavelength of the LD 2 changes nonlinearly. Accordingly, in this embodiment, with respect to the relationship between the LD shutdown length and the fluctuation amount of the light oscillation wavelength of the LD 2 illustrated in FIG. 6, a plurality of points serving as measurement points or calculation points are selected within a region of the LD shutdown length from zero to Tₛₚₐₙ, and the plurality of points are approximated in advance by the use of a nonlinear approximate expression, such as a polynomial approximate expression of a quadratic or higher form. Specifically, as regards the fluctuation amount Δλ′ of the light oscillation wavelength, a nonlinear approximate expression, which is a function of the elapsed time “t” since the point in time when the LD shutdown signal changed to the significant value, is determined in advance. The target temperature calculation circuit 8 holds this nonlinear approximate expression.

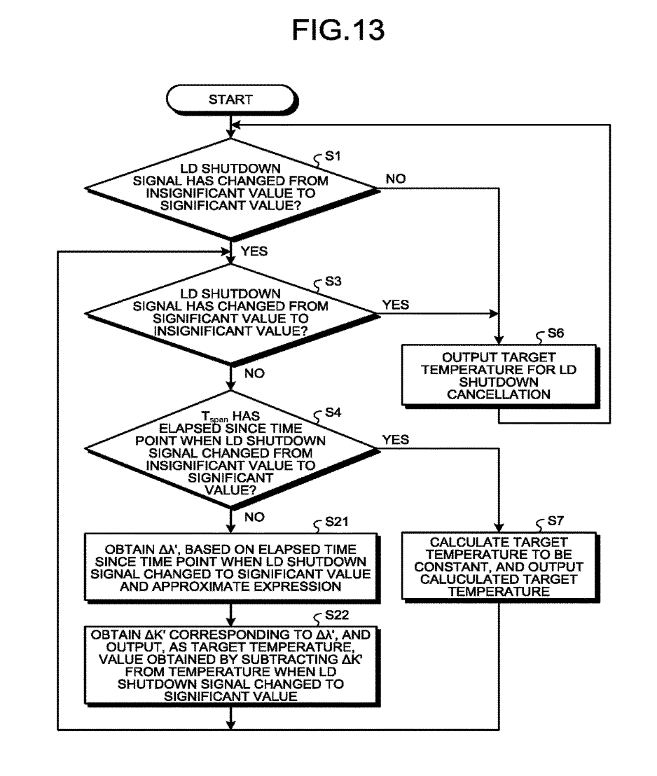

FIG. 13 is a flowchart illustrating an example of a target temperature calculation procedure by the target temperature calculation circuit 8 according to this embodiment. The target temperature calculation circuit 8 determines whether the LD shutdown signal has changed from the insignificant value to the significant value (step S1). When the LD shutdown signal has changed from the insignificant value to the significant value (Yes at step S1), the target temperature calculation circuit 8 determines whether the LD shutdown signal has changed from the significant value to the insignificant value (step S3). When the LD shutdown signal has not changed from the significant value to the insignificant value (No at step S3), the target temperature calculation circuit 8 determines whether Tₛₚₐₙ has elapsed since the point in time when the LD shutdown signal changed from the insignificant value to the significant value (step S4).

When Tₛₚₐₙ has not elapsed since the point in time when the LD shutdown signal changed from the insignificant value to the significant value (No at step S4), the target temperature calculation circuit 8 obtains Δλ′, on the basis of the elapsed time “t” since the point in time when the LD shutdown signal changed to the significant value and the nonlinear approximate expression (step S21). Then, the target temperature calculation circuit 8 obtains ΔK′ corresponding to Δλ′ on the basis of Δλ′ and the temperature versus wavelength characteristics, and outputs a value obtained by subtracting ΔK′ from the target temperature for the LD shutdown cancellation, as a target temperature, to the current calculation circuit 6 (step S22), and then the procedure goes back to step S3.

At step S1, when the LD shutdown signal has not changed from the insignificant value to the significant value (No at step S1), the target temperature calculation circuit 8 outputs the target temperature for the LD shutdown cancellation to the current calculation circuit 6 (step S6), and the procedure goes back to step S1. At step S3, when the target temperature calculation circuit 8 determines that the LD shutdown signal has changed from the significant value to the insignificant value (Yes at step S3), the procedure proceeds to step S6. At step S4, when determining that Tₛₚₐₙ has elapsed since the point in time when the LD shutdown signal changed from the insignificant value to the significant value (Yes at step S4), the target temperature calculation circuit 8 calculates a target temperature so that the target temperature becomes constant, and outputs the calculated target temperature to the current calculation circuit 6 (step S7), and then the procedure goes back to step S3. Here, the target temperature set at step S7 is the same as that of the first embodiment.

As described above, the target temperature calculation circuit 8 according to this embodiment holds an approximate expression that approximates the relationship between the LD shutdown length and the wavelength fluctuation amount of the light oscillation wavelength of the LD 2 by means of nonlinear approximation. Until the elapsed time since the LD shutdown start becomes Tₛₚₐₙ, the target temperature calculation circuit 8 obtains a wavelength fluctuation amount, on the basis of the elapsed time since the LD shutdown start and the approximate expression. Then, the target temperature calculation circuit 8 calculates a temperature change amount corresponding to the obtained wavelength fluctuation amount, and further calculates a target temperature to be set in the current calculation circuit 6 as a value obtained by subtracting the temperature change amount from the first target temperature.

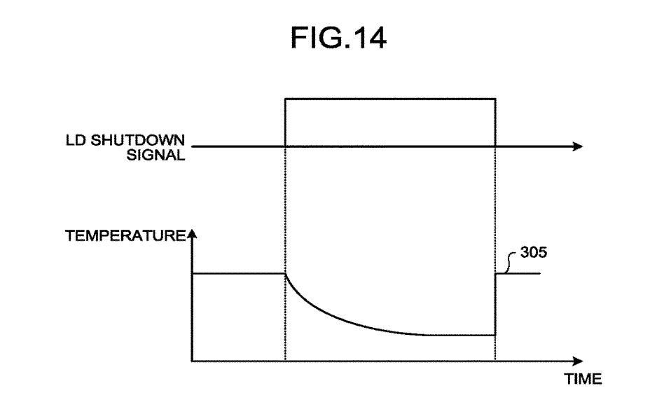

FIG. 14 illustrates an example of a target temperature calculated by a target temperature calculation process and to be set in the current calculation circuit 6, according to this embodiment. The upper side of FIG. 14 illustrates the LD shutdown signal, and the lower side of FIG. 14 illustrates a target temperature 305 to be set in the current calculation circuit 6. In the first embodiment, the target temperature is linearly changed after the LD shutdown start. However, in this embodiment, as illustrated in FIG. 14, the target temperature is nonlinearly changed after the LD shutdown start. With this arrangement, the target temperature decreasing amount corresponding to the light oscillation wavelength fluctuation amount after the shutdown start can be obtained more accurately than in the first embodiment. Thus, the light oscillation wavelength fluctuation when the shutdown duration time is short can be reduced. The operations of this embodiment other than those described above are the same as those of the first embodiment.

In the first embodiment, an example is shown where the target temperature to be set in the current calculation circuit 6 is linearly lowered until the elapsed time since the LD shutdown start becomes Tₛₚₐₙ. In this embodiment, an example is shown where the target temperature to be set in the current calculation circuit 6 is nonlinearly lowered. Thus, regardless which of the linear or nonlinear is adopted, it suffices that, until the elapsed time since the LD shutdown start becomes Tₛₚₐₙ, the target temperature to be set in the current calculation circuit 6 is decided to be monotonously lowered from the first target temperature to the second target temperature. Specifically, the target temperature calculation circuit 8 according to each of the first embodiment and the second embodiment sets the first target temperature as the target temperature described above during the LD shutdown cancellation time period, sets the target temperature such that the target temperature described above monotonously decreases from the first target temperature to the second target temperature that is lower than the first target temperature until a certain time has elapsed since the LD shutdown start, and sets the second target temperature as the target temperature when the elapsed time since the LD shutdown start becomes the certain time or more.

As described above, in this embodiment, by the use of a result of nonlinear approximation of the relationship between the LD shutdown length and the fluctuation amount of the light oscillation wavelength of the LD 2, and control is performed such that the target temperature to be set in the current calculation circuit 6 is nonlinearly and gradually lowered until the elapsed time since the LD shutdown start becomes Tₛₚₐₙ, and the target temperature is set to be constant when the elapsed time since the LD shutdown start becomes Tₛₚₐₙ or more. Consequently, the fluctuation in the light oscillation wavelength of the LD 2 can be reduced more accurately as compared with the first embodiment.

### Third Embodiment

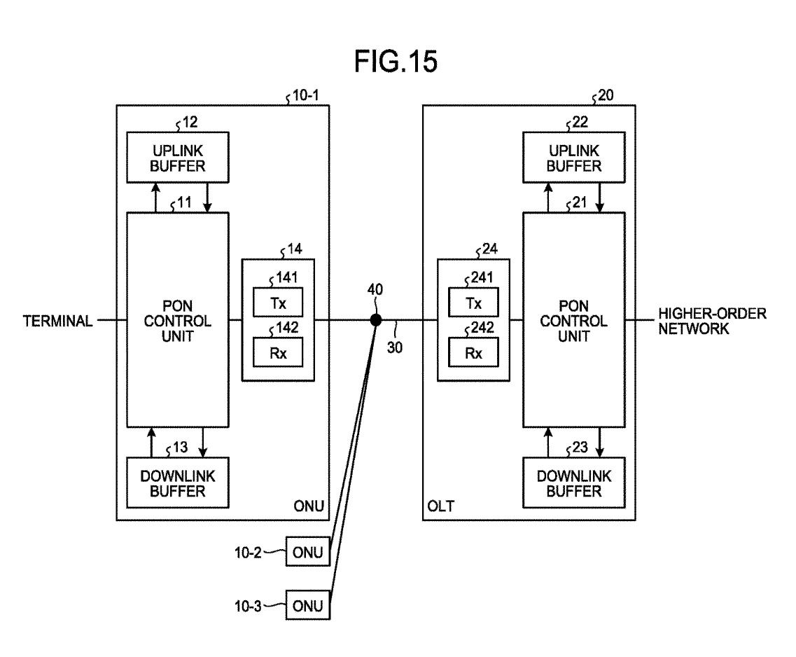

FIG. 15 illustrates a configuration example of an optical communication system according to a third embodiment. The optical communication system illustrated in FIG. 15 includes an OLT (Optical Line Terminal) 20 serving as a master station device and ONUs (Optical Network Unit) 10-1 to 10-3 serving as slave station devices. FIG. 15 illustrates three ONUs; however, the number of ONUs is not limited to this. In this embodiment, an explanation will be given of an example where an optical transmitter 100 described in the first embodiment or second embodiment is equipped in each of the ONUs 10-1 to 10-3.

The OLT 20 is connected to the ONUs 10-1 to 10-3 through an optical fiber 30 serving as an optical communication path via an optical star coupler 40. The optical star coupler 40 divides the mainline optical fiber 30 connected to the OLT 20 into the fibers equivalent in number to the ONUs 10-1 to 10-3.

For example, the ONU 10-1 includes a PON control unit 11 serving as a control circuit for performing processes on the ONU side on the basis of a PON protocol, an uplink buffer 12 serving as a buffer memory for storing transmission data to the OLT 20, i.e., uplink data, a downlink buffer 13 serving as a buffer memory for storing reception data from the OLT 20, i.e., downlink data, and an optical transceiver unit 14. Further, the ONU 10-1 may include also a WDM coupler, in the case where the ONU 10-1 performs wavelength multiplexing. The ONUs 10-2 and 10-3 have the same configuration as that of the ONU 10-1. Hereinafter, when the ONUs are individually identified, each of the ONUs will be referred to with a branch number, as the ONU 10-1, and, when the ONUs 10-1 to 10-3 are generally described without discrimination as to which one of the ONUs 10-1 to 10-3 is, they will be referred to as “ONU”.

The optical transceiver unit 14 includes an optical transmitter 141 that converts an electric signal to be transmitted to the OLT 20 into an optical signal, and an optical receiver 142 that converts an optical signal received from the OLT 20 into an electric signal. Here, in FIG. 15, the optical transmitter is abbreviated to “Tx”, and the optical receiver is abbreviated to “Rx”. The optical transmitter 141 is the optical transmitter 100 described in the first embodiment or second embodiment.

The OLT 20 includes a PON control unit 21 serving as a control circuit for performing processes on the OLT side on the basis of the PON protocol, an uplink buffer 22 serving as a buffer for storing uplink data received from the ONUs 10-1 to 10-3, a downlink buffer 23 serving as a buffer for storing downlink data which has been received from a higher-order network and is to be transmitted to the ONUs 10-1 to 10-3, and an optical transceiver unit 24 that performs transmission and reception of optical signals. Further, the OLT 20 may include also a WDM coupler, when the ONU 20 performs wavelength multiplexing. The optical transceiver unit 24 includes an optical transmitter 241 that converts an electric signal to be transmitted to the ONUs 10-1 to 10-3 into an optical signal, and an optical receiver 242 that converts an optical signal received from the ONUs 10-1 to 10-3 into an electric signal.

Here, the PON protocol described above is a control protocol used for a sub-layer of Layer 2, such as MAC (Media Access Control) layer. For example, the PON protocol is MPCP (Multi-Point Control Protocol) or OAM (Operation Administration and Maintenance) that are prescribed by IEEE (The Institute of Electrical and Electronics Engineers). The PON protocol to be adopted to the present invention is not limited to these examples, and any protocol can be adopted.

In this embodiment, an explanation will be given of an example where the optical transmitter 141 of the optical transceiver unit 14 of the ONU is the optical transmitter according to the first embodiment or second embodiment. However, it is sufficient that the optical communication device equipped with an optical transmitter according to this embodiment is an optical communication device equipped with a control unit that inputs a signal similar to the LD shutdown signal into the optical transmitter of this embodiment; accordingly, the optical communication device is not limited to the ONU illustrated in FIG. 15. Further, the laser diode and the temperature control circuit according to the first embodiment or second embodiment may be equipped in a device other than an optical communication device.

The OLT 20 stores downlink data received from the higher-order network into the downlink buffer 23. The PON control unit 21 reads the downlink data stored in the downlink buffer 23 and transmits the data toward the ONUs 10-1 to 10-3 via the optical transmitter 241. Further, the PON control unit 21 performs allocation of uplink bands to the ONUs 10-1 to 10-3, power saving control of the ONUs 10-1 to 10-3, and/or the like. Further, the PON control unit 21 generates a control signal, such as a signal regarding power saving control that includes notice of a transmission stop time period of the ONUs 10-1 to 10-3, or a transmission permission signal for notifying a band allocation result of uplink bands. The PON control unit 21 transmits the control signal toward the ONUs 10-1 to 10-3 via the optical transmitter 241.

In the ONU 10-1, the optical receiver 142 converts an optical signal received from the OLT 20 into an electric signal, and inputs the electric signal into the PON control unit 11. The PON control unit 11 stores downlink data received from the OLT 20 via the optical transceiver unit 14 into the downlink buffer 13. Further, the PON control unit 11 performs an operation based on a control signal received from the OLT 20. Further, the PON control unit 11 reads downlink data from the downlink buffer 13, and transmits the data to a terminal or the like addressed by the downlink data.

In the ONU 10-1, on the basis of a signal transmitted from the OLT 20 or a determination of the PON control unit 11, the PON control unit 11 generates an LD shutdown signal, and outputs the signal to the optical transmitter 141. Specifically, for example, when detecting a defect on a transmission path or during a transmission prohibiting time zone in accordance with an instruction from the OLT 20, the PON control unit 11 generates an LD shutdown signal to perform an LD shutdown. Here, in the example of FIG. 15, the PON control unit 11 generates the LD shutdown signal; however, a component for generating the LD shutdown signal may be provided separately from the PON control unit 11.

The configurations illustrated in the above embodiments are mere examples of the present invention, and they may be combined with other known technologies. Further, the configurations may be partly omitted or changed without departing from the gist of the present invention.

### REFERENCE SIGNS LIST

1 temperature control circuit, 2 LD, 3 LD driver, 4 TEC, 5 temperature detector, 6 current calculation circuit, 7 current control circuit, 8 target temperature calculation circuit, 10-1 to 10-3 ONU, 11, 21 PON control unit, 12, 22 uplink buffer, 13, 23 downlink buffer, 14, 24 optical transceiver unit, 20 OLT, 30 optical fiber, 40 optical star coupler, 100, 141, 241 optical transmitter, 142, 242 optical receiver, 200 control circuit, 201 input unit, 202 processor, 203 memory, 204 output unit.

1: A temperature control circuit comprising:
a temperature detector to detect temperature of a laser diode;
a thermoelectric element to control temperature of the laser diode by performing heat absorption and radiation in accordance with an amount of current flowing therethrough;
a current calculation circuit to calculate an amount of current caused to flow through the thermoelectric element on a basis of a temperature of the laser diode detected by the temperature detector and a target temperature;
a current control circuit to control a current caused to flow through the thermoelectric element on a basis of an amount of current calculated by the current calculation circuit; and
a target temperature calculation circuit to set a first target temperature as the target temperature, during a time period in which the light emission stop state of the laser diode is cancelled on a basis of a light emission stop signal that indicates whether to cause the laser diode to be in a light emission stop state, to set the target temperature so as to monotonously decrease from the first target temperature to a second target temperature that is lower than the first target temperature until a certain time elapses since the light emission stop state of the laser diode has started in the light emission stop signal, and to set the second target temperature as the target temperature when the certain time elapses since the light emission stop state of the laser diode has started in the light emission stop signal, wherein
the certain time is calculated on a basis of a relationship between a duration time of the light emission stop state of the laser diode and a wavelength fluctuation amount of a light oscillation wavelength of the laser diode.

2: The temperature control circuit according to claim 1, wherein, when a relationship between a duration time of the light emission stop state of the laser diode and a wavelength fluctuation amount of a light oscillation wavelength of the laser diode is used to calculate a wavelength fluctuation amount, serving as a first wavelength fluctuation amount, that corresponds to a minimum value of the duration time of the light emission stop state of the laser diode, with which a change amount in the wavelength fluctuation amount with respect to the duration time of the light emission stop state of the laser diode becomes less than a threshold,
the certain time is a value of the duration time of the light emission stop state of the laser diode, which corresponds to a second wavelength fluctuation amount that is obtained by subtracting a permissible fluctuation amount from the first wavelength fluctuation amount.

3: The temperature control circuit according to claim 1, wherein the target temperature calculation circuit linearly lowers the target temperature with an inclination of a value, which is calculated by dividing, by the certain time, a value obtained by subtracting the second target temperature from the first target temperature, until the certain time elapses since the light emission stop state of the laser diode has started in the light emission stop signal.

4: The temperature control circuit according to claim 2, wherein the target temperature calculation circuit holds an approximate expression that approximates the relationship between the duration time of the light emission stop state of the laser diode and the wavelength fluctuation amount of the light oscillation wavelength of the laser diode by means of nonlinear approximation, and, until the certain time elapses since the light emission stop state of the laser diode has started in the light emission stop signal, the target temperature calculation circuit operates to obtain the wavelength fluctuation amount on a basis of an elapsed time since the light emission stop state of the laser diode has started and the approximate expression; to calculate a temperature change amount corresponding to the obtained wavelength fluctuation amount; and to calculate the target temperature as a value obtained by subtracting the temperature change amount from the first target temperature.

5: A transmitter comprising:
a laser diode; and
a temperature control circuit according to claim 1, which controls temperature of the laser diode.

6: A temperature control method comprising:
detecting temperature of a laser diode;
performing heat absorption and radiation to change temperature of the laser diode on a basis of a temperature of the laser diode detected in the detecting and a target temperature; and
setting a first target temperature as the target temperature, during a time period in which the light emission stop state of the laser diode is cancelled on a basis of a light emission stop signal that indicates whether to cause the laser diode into a light emission stop state, setting the target temperature so as to monotonously decrease from the first target temperature to a second target temperature that is lower than the first target temperature until a certain time has elapsed since the light emission stop state of the laser diode was started in the light emission stop signal, and setting the second target temperature as the target temperature when the certain time elapses since the light emission stop state of the laser diode has started in the light emission stop signal, wherein
the certain time is calculated on a basis of a relationship between a duration time of the light emission stop state of the laser diode and a wavelength fluctuation amount of a light oscillation wavelength of the laser diode.
